(19) United States
(12) Patent Application Publication
(10) Pub. No.: US 2026/0312584 A1
(43) Pub. Date: Oct. 8, 2026

(54) SWITCH DEVICE

(71) Applicant: KABUSHIKI KAISHA TOKAI RIKA DENKI SEISAKUSHO, Aichi (JP)

(72) Inventors: Takao IMAI, Aichi (JP); Masayoshi AMANO, Aichi (JP); Kazuo DODOMEKI, Aichi (JP); Takuya GOTO, Aichi (JP); Itaru WATANABE, Aichi (JP); Takeshi FUJIMOTO, Aichi (JP)

(73) Assignee: KABUSHIKI KAISHA TOKAI RIKA DENKI SEISAKUSHO, Aichi (JP)

(21) Appl. No.: 19/629,197

(22) Filed: Mar. 26, 2026

(30) Foreign Application Priority Data
Apr. 8, 2025 (JP) 2025-063729

(51) Int. Cl. H03K 17/94; H03K 17/96; H03K 17/965

(52) U.S. Cl. CPC H03K 17/941; H03K 17/9631; H03K 17/9638; H03K 17/965

(57) ABSTRACT

A switch device includes a panel including an operation area where an operation is performed by a user, a light source that emits light onto the operation area, a light guide that guides light emitted from the light source to the operation area, a sensor sheet that detects proximity or contact of a finger of the user to or with the operation area, is sandwiched and held between the light guide and the panel, and transmits light output from the light guide, and a pressing mechanism that generates a pressing force interacting between the panel, the sensor sheet, and the light guide.

### CROSS-REFERENCE TO RELATED APPLICATIONS

The present patent application claims the priority of Japanese patent application No. 2025/063729 filed on Apr. 8, 2025, and the entire contents of Japanese patent application No. 2025/063729 hereby incorporated by reference.

### TECHNICAL FIELD

The present invention relates to a switch device.

### BACKGROUND ART

Patent Literature 1 discloses a switch device that uses a touch sensor and is configured such that light in the shapes of marks indicating operation functions appears in operation areas (i.e., on a touch surface). In the switch device described in Patent Literature 1, the touch sensor is provided with a light-shielding layer on which through-holes having the shapes of the marks are formed. Then, in the switch device described in Patent Literature 1, light emitted from a light source can pass through a light guide and then through the through-holes on the light-shielding layer of the touch sensor and illuminates the operation areas, and light in the shaped of the marks thereby appear in the operation areas.

### CITATION LIST

### Patent Literature

Patent Literature 1: JP 2015/85832A

### SUMMARY OF INVENTION

In the switch device described in Patent Literature 1, however, an air layer is present between the light guide and the touch sensor, and since light reflection is likely to occur at the interface with this air layer, light loss is likely to occur from the light source to the operation area.

It is an object of the invention to provide a switch device capable of suppressing loss of light from a light source to an operation area.

An aspect of the invention provides a switch device, comprising:

a panel comprising an operation area where an operation is performed by a user;

a light source that emits light onto the operation area;

a light guide that guides light emitted from the light source to the operation area;

a sensor sheet that detects proximity or contact of a finger of the user to or with the operation area, is sandwiched and held between the light guide and the panel, and transmits light output from the light guide; and

a pressing mechanism that generates a pressing force interacting between the panel, the sensor sheet, and the light guide.

### Advantageous Effects of Invention

According to an embodiment of the invention, it is possible to provide a switch device capable of suppressing loss of light from a light source to an operation area.

### BRIEF DESCRIPTION OF DRAWINGS

FIG. 1 is a front view showing a switch device in the first embodiment.

FIG. 2 is a cross-sectional view taken along line II-II in FIG. 1 as viewed in the arrow direction.

FIG. 3 is a cross-sectional view taken along line III-III in FIG. 1 as viewed in the arrow direction.

FIG. 4 is a cross-sectional view showing the switch device in the first embodiment, taken orthogonal to a front-rear direction.

FIG. 5 is a perspective view showing a light guide in the first embodiment.

FIG. 6 is a front view showing four light guides and a sensor sheet in the first embodiment.

FIG. 7 is a cross-sectional view showing the switch device in the first embodiment when a pressing operation is being performed in an operation area.

FIG. 8 is a cross-sectional view showing the switch device in the second embodiment, taken orthogonal to an up-down direction.

FIG. 9 is a cross-sectional view showing the switch device in the second embodiment, taken orthogonal to a left-right direction.

### DESCRIPTION OF EMBODIMENTS

### First embodiment

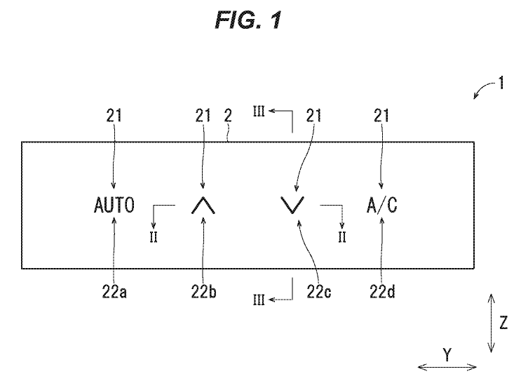

The first embodiment of the invention will be described with reference to FIGS. 1 to 7. The embodiment below is described as a preferred example for implementing the invention. Although some part of the embodiment specifically illustrates various technically preferable matters, the technical scope of the invention is not limited to such specific aspects.

FIG. 1 is a front view showing a switch device 1 in the first embodiment. The switch device 1 in the first embodiment is mounted on, e.g., a vehicle such as an automobile and is used to operate a predetermined in-vehicle device. In the first embodiment, the switch device 1 is attached to an automobile instrument panel and is used to operate an air conditioner. However, the intended use of the switch device 1 is not limited thereto, and the switch device 1 may be used to operate an in-vehicle device other than the air conditioner, such as audio equipment. In addition, the switch device 1 is not limited to a device to be installed in a vehicle.

As shown in FIG. 1, in the first embodiment, the switch device 1 has a panel 2 provided at a position allowing an occupant of a vehicle as a user to see it. The panel 2 has operation areas 21 on which operations are performed by a finger of the user. Marks 22a to 22d representing functions to be executed by the operation are lit in the operation areas 21. In the first embodiment, as an example, the switch device 1 has four operation areas 21 to respectively instruct the air conditioner to perform following functions: (1) turn on/off the automatic control function, (2) increase temperature, (3) decrease temperature, and (4) turn on/off the compressor. Then, in the four operation areas 21, the following marks light up: the mark 22a indicating turn on/off the auto control function, the mark 22b indicating instruction to increase temperature, the mark 22c indicating instruction to decrease temperature, and the mark 22d indicating turn on/off the compressor. In this regard, the number of operation areas 21 is not particularly limited.

In the switch device 1 of the first embodiment, the marks 22a to 22d in the operation areas 21 are normally unlit and not visible. On the other hand, when proximity of the user’s finger is detected within a predetermined range from the panel 2 by a sensor sheet 8 (described later), all the marks 22a to 22d light up. Then, when a mechanical switch 6 (described later) detects that an operation area 21 has been pressed by the user’s finger, the function assigned to the pressed operation area 21 is executed.

Next, the general overall configuration of the switch device 1 will be described.

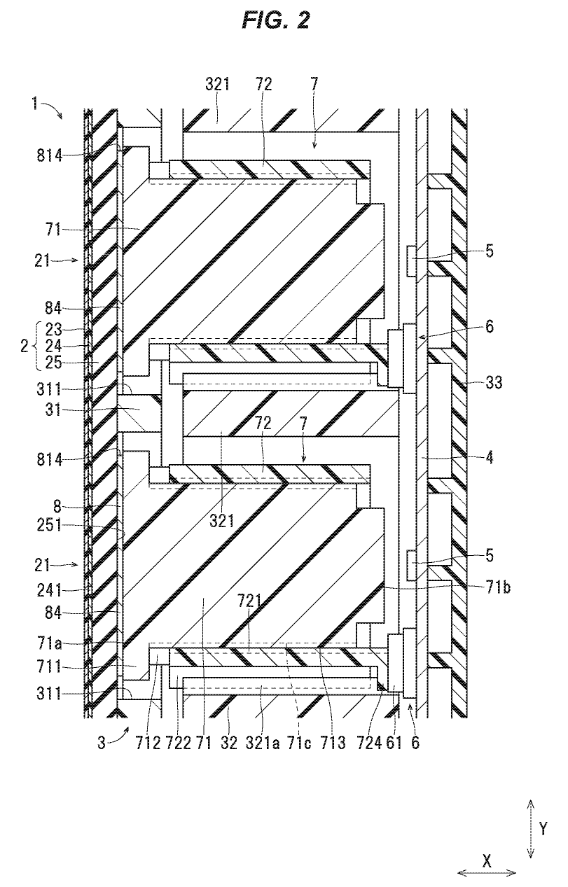

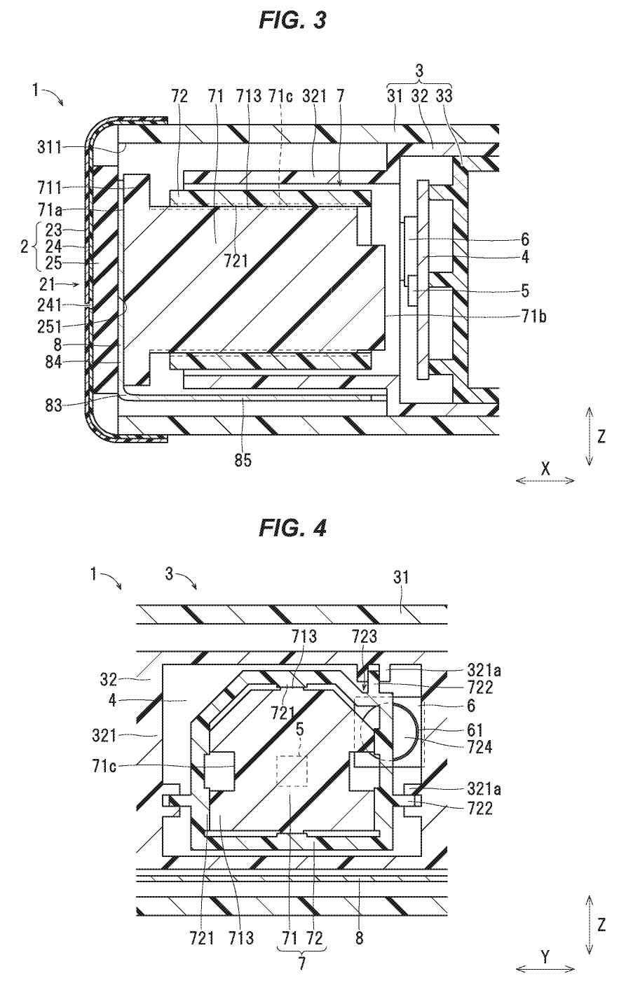

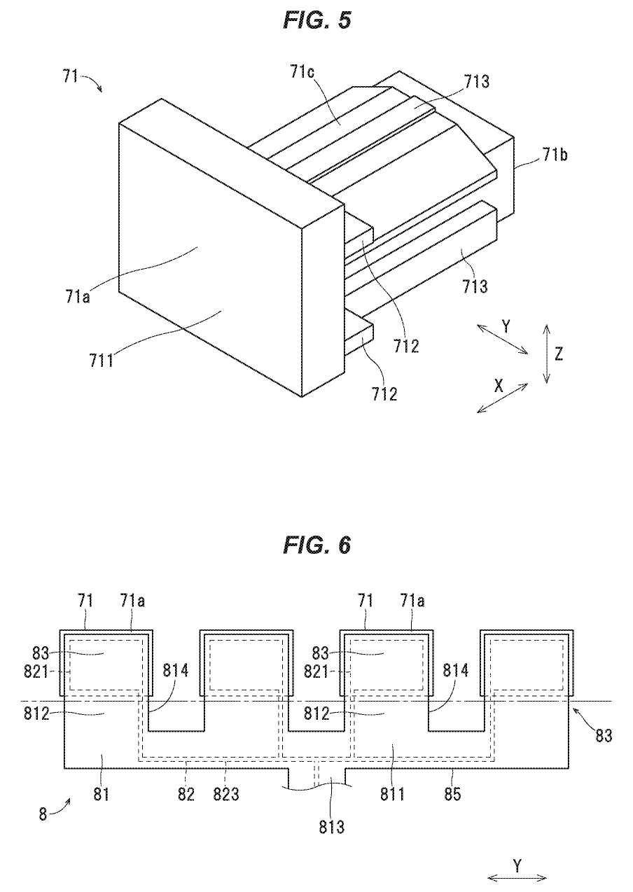

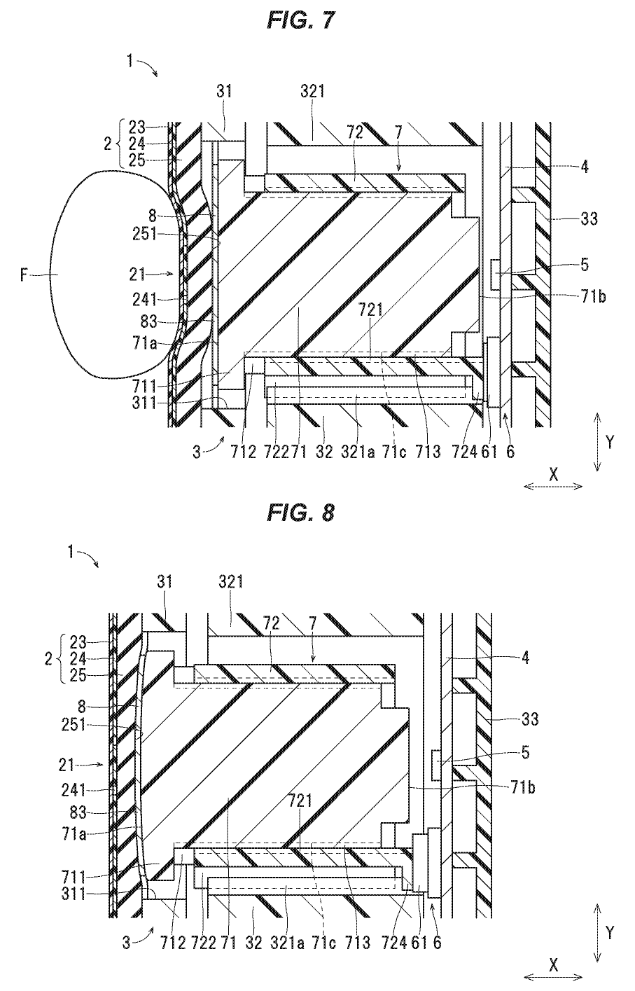

FIG. 2 is a cross-sectional view taken along line II-II in FIG. 1 as viewed in the arrow direction. FIG. 3 is a cross-sectional view taken along line III-III in FIG. 1 as viewed in the arrow direction. FIG. 4 is a cross-sectional view showing the switch device 1, taken orthogonal to the front-rear direction. FIG. 5 is a perspective view showing a light guide 71. FIG. 6 is a front view showing four light guides 71 and the sensor sheet 8. FIG. 7 is a cross-sectional view showing the switch device 1 when a pressing operation is being performed in the operation area 21. FIG. 7 shows a cross-section of the switch device 1 when cut at the same location as the cross-section in FIG. 2.

As shown in FIGS. 2 and 3, the switch device 1 includes the panel 2, a housing 3, a substrate 4, a light source 5, the mechanical switch 6, the light guide 71, an enclosing member 72, and the sensor sheet 8. As shown in FIG. 1, four operation areas 21 are provided on the panel 2. As shown in FIGS. 2 and 3, the housing 3 is configured such that the panel 2 is fixed thereto and each component of the switch device 1 is housed therein. The substrate 4 is fixed to the housing 3 and has the light source 5 and the mechanical switch 6 mounted thereon.

The light source 5 emits light onto the operation area 21. The mechanical switch 6 detects a pressing operation when pressed by a force during the pressing operation on the operation area 21 that is applied through the sensor sheet 8 and the light guide 71. The light guide 71 guides the light emitted from the light source 5 to the operation area 21. The enclosing member 72 surrounds around the light guide 71 and is fixed to the light guide 71. In the first embodiment, four light sources 5, four mechanical switches 6, four light guides 71 and four enclosing members 72 are provided so as to respectively correspond to the four operation areas 21.

The sensor sheet 8 detects proximity or contact of a finger of the user to or with the operation areas 21. The sensor sheet 8 is sandwiched and held between the panel 2 and the light guide 71, and transmits light output from the light guide 71.

The switch device 1 in the first embodiment includes a pressing mechanism that generates a pressing force interacting between the panel 2, the sensor sheet 8, and the light guide 71. In the first embodiment, the mechanical switch 6 serves as an elastic unit that presses the enclosing member 72 and the light guide 71 toward the panel 2 by its elastic force, and the pressing mechanism is thereby realized. The pressing mechanism ensures close contact between the light guide 71, the sensor sheet 8 and the panel 2, thereby suppressing light loss caused by the presence of an air layer therebetween.

Next, the switch device 1 in the first embodiment will be described in detail.

In the first embodiment, the arrangement direction of the light source 5, the light guide 71 and the panel 2 is defined as the front-rear direction X, one side in the front-rear direction X, which is the panel 2 side relative to the light source 5, is defined as the front, and the opposite side is defined as the rear. In addition, the arrangement direction of the four operation areas 21 is defined as the left-right direction Y. Furthermore, the direction perpendicular to both the front-rear direction X and the left-right direction Y is defined as the up-down direction Z.

The panel 2 is formed by laminating an exterior panel 23, a mark-forming panel 24, and an elastic panel 25 in this order. The exterior panel 23 constitutes the outermost surface of the panel 2. The exterior panel 23 has operation areas 21 on its front surface that are touched by the user’s finger during a pressing operation. The exterior panel 23 is formed of a material that allows light emitted from the light source 5 to pass through. In this regard, the exterior panel 23 does not need to be transparent to the light emitted from the light source 5 as long as the material does not completely block the light emitted from the light source 5.

The mark-forming panel 24 is provided on the rear surface of the exterior panel 23. The mark-forming panel 24 is formed of a light-blocking material that blocks the light emitted from the light source 5, and holes 241 in the shapes of the marks 22a to 22d are formed on the mark-forming panel 24. The light emitted from the light source 5 passes through the holes 241, allowing the user to see light in the shapes of the marks 22a to 22d. As shown in FIG. 7, the exterior panel 23 and the mark-forming panel 24 are formed thin enough to flex when the user presses the operation area 21 with a finger F.

As shown in FIGS. 2 and 3, the elastic panel 25 is provided on the rear surface of the mark-forming panel 24. The elastic panel 25 faces all the four light guides 71 from the front. The elastic panel 25 is formed by shaping an elastic material such as rubber into a sheet shape. The elastic panel 25 is formed thicker than the exterior panel 23 and the mark-forming panel 24, and is thus easily elastically deformed. When the operation area 21 is not being operated by the user, the elastic panel 25 receives a pressing force from the mechanical switch 6 through the sensor sheet 8, the light guide 71 and the enclosing member 72 and is elastically deformed. In addition, as shown in FIG. 7, the elastic panel 25 is also elastically deformed when the user presses the operation area 21.

As shown in FIGS. 2 and 3, the housing 3 has a first housing 31, a second housing 32, and a third housing 33. The first housing 31, together with the panel 2, forms the main exterior appearance of the switch device 1, and the second housing 32 and the third housing 33 are fixed inside the first housing 31. The first housing 31 has four openings 311 in which front end portions 711 of the light guides 71 are respectively arranged. The front portion of the first housing 31 including the four openings 311 is covered with the panel 2.

The second housing 32 has four cylindrical portions 321 respectively housing four translationally moving units 7 each composed of the light guide 71 and the enclosing member 72. The cylindrical portions 321 are formed side by side in the left-right direction Y, and are open on both sides in the front-rear direction X.

As shown in FIG. 4, in the first embodiment, the cylindrical portion 321 is formed in a substantially rectangular cylindrical shape along the left-right direction Y and the up-down direction Z. The cylindrical portion 321 has plural guide grooves 321a that guide translational movement of the translationally moving unit 7. The guide groove 321a is a groove extending along the front-rear direction X which is the direction of translational movement of the translationally moving unit 7 relative to the cylindrical portion 321. In the first embodiment, the guide grooves 321a are formed on three different walls out of the four walls constituting the cylindrical portion 321, hence, the orientation of the translationally moving unit 7 is unlikely to become unstable during the translational movement. In addition, one of the four walls constituting the cylindrical portion 321 does not have the guide groove 321a, allowing the entire switch device 1 to be small in size.

As shown in FIG. 3, the third housing 33 is fixed to the second housing 32 so as to close a rear opening of the second housing 32. Then, the substrate 4 is fixed to the third housing 33.

As shown in FIGS. 2 and 3, the substrate 4 is composed of, e.g., a rigid printed circuit board, and is arranged in an orientation where its normal direction coincides with the front-rear direction X. In the first embodiment, the substrate 4 is formed to be long in the left-right direction Y and faces all the plural light guides 71 from the rear. On the front surface of the substrate 4, four light sources 5 and four mechanical switches 6 are mounted corresponding to the four operation areas 21.

The light source 5 illuminates the panel 2 with light through the light guide 71 and the sensor sheet 8, causing the mark 22a – 22d to be lit on the panel 2. The light source 5 emits light with a wide divergence toward the front and is composed of, e.g., an LED (Light-Emitting Diode). As shown in FIG. 4, the light source 5 is located behind the approximate center position of a rear surface 71b of the light guide 71.

As shown in FIG. 2, the mechanical switch 6 is a mechanical-type switch in which the on/off state of contacts is switched in response to a pressing operation performed on the operation area 21 by the user. The mechanical switch 6 has an elastic member resisting a pressing operation, and is composed of, e.g., a tact switch, etc. A push button 61 of the mechanical switch 6 is in contact with a push portion 724 of the enclosing member 72 (described later). As shown in FIG. 7, when a pressing operation is performed on the operation area 21, the panel 2 and the sensor sheet 8 flex, the push button 61 is pressed by the push portion 724 as the translationally moving unit 7 translationally moves rearward, and the mechanical switch 6 detects the pressing operation.

In the first embodiment, the mechanical switch 6 also serves as an elastic unit that elastically presses the translationally moving unit 7 toward the panel 2. When an operation is not being performed by the user, the mechanical switch 6 is arranged in a state in which pressure is applied to its internal elastic member, i.e., in a preloaded state. Thus, the mechanical switch 6 presses the translationally moving unit 7 toward the panel 2 by an elastic restoring force of the internal elastic member.

The light guide 71 is formed of a material transmitting the light emitted from the light source 5. The light guide 71 is formed of, e.g., a light-transmitting resin, or glass, etc. The light guide 71 is designed so that light entering the interior from the rear surface 71b is guided to a front surface 71a and extracted from the front surface 71a. The front surface 71a and the rear surface 71b of the light guide 71 are formed in a flat shape in the first embodiment. The example in which the normal directions to the front surface 71a and the rear surface 71b coincide with the front-rear direction X is described in the first embodiment, but at least one of these normal directions may be a direction inclined relative to the front-rear direction X. Among light incident on the light guide 71, a portion traveling toward an outer peripheral surface 71c of the light guide 71 advances while being reflected at the outer peripheral surface 71c of the light guide 71 and is guided to the front surface 71a. From the viewpoint of facilitating light reflection at the outer peripheral surface 71c of the light guide 71, the light guide 71 and the substance on the outer side of the light guide 71 preferably have a large difference in refractive index. Therefore, it is preferable that the outer peripheral surface 71c of the light guide 71 be exposed to air as much as possible.

As shown in FIG. 5, the light guide 71 has a substantially columnar shape formed along the front-rear direction X, and its front end portion 711 has a shape that widens outward. This makes it easier to ensure that the front surface 71a of the light guide 71 has an enough area, and the sensor sheet 8 is pressed against the panel 2 over a wide area. This mitigates localized stress concentration on the sensor sheet 8. As shown in FIGS. 2 and 3, the front end portion 711 is arranged at a position on the front side relative to the enclosing member 72 and the cylindrical portion 321.

As shown in FIGS. 2 and 5, the light guide 71 has a contact portion 712 that is formed in a protruding manner and is in contact with the enclosing member 72 from the front side. In the first embodiment, the contact portion 712 is in contact with the front end of the enclosing member 72. The contact portion 712 suppresses relative sliding between the light guide 71 and the enclosing member 72 during when the translationally moving unit 7 translationally moves rearward due to a pressing operation performed on the operation area 21 and also during when the translationally moving unit 7 translationally moves forward upon the release of the pressing operation.

As shown in FIGS. 4 and 5, plural fixing protrusions 713 are formed on the outer peripheral portion of the light guide 71 at a portion to be inserted into the enclosing member 72. In the first embodiment, the plural fixing protrusions 713 are formed so as to protrude toward up, down, left and right. The light guide 71 is fixed to the enclosing member 72 at the fixing protrusions 713. In the first embodiment, the enclosing member 72 also has fixing protrusions 721 on the inner peripheral portion at plural locations that face the fixing protrusions 713. Then, the light guide 71 is press-fitted into the enclosing member 72 so that the fixing protrusions 713 come into contact with the fixing protrusions 721, and the light guide 71 is thereby fixed to the enclosing member 72. The portion between the light guide 71 and the enclosing member 72 is a space except for the contact points between the plural fixing protrusions 713 and the plural fixing protrusions 721. As a result, light reflection is likely to occur at the outer peripheral surface 71c of the light guide 71, and the light incident on the light guide 71 from the rear surface 71b is likely to be guided to the front surface 71a.

As shown in FIG. 5, the fixing protrusions 713 are formed to be long in the front-rear direction X. In the first embodiment, each fixing protrusion 713 is formed so that its rear end is positioned at a distance from the rear surface 71b of the light guide 71. This ensures a sufficient creepage distance from the sliding portion between the cylindrical portion 321 and the enclosing member 72 (i.e., the guide groove 321a and a guide piece 722 described later) to the rear surface 71b of the light guide 71, thereby suppressing the reach of lubricant or foreign matter, etc. present on the sliding portion to the rear surface 71b. As a result, loss of light from the light source 5 to the operation area 21 is suppressed.

As shown in FIGS. 2 to 4, the enclosing member 72 has a cylindrical shape and surrounds the light guide 71 all around. The enclosing member 72 spatially separates the light guide 71 from the sliding portion between the cylindrical portion 321 and the enclosing member 72, thereby suppressing the reach of lubricant on the sliding portion to the light guide 71.

As shown in FIG. 4, three guide pieces 722, which respectively engage the three guide grooves 321a of the cylindrical portion 321 and can slide in the front-rear direction X relative to the guide grooves 321a, are formed on the outer peripheral portion of the enclosing member 72. The translationally moving unit 7 composed of the enclosing member 72 and the light guide 71 is guided in translational movement in the front-rear direction X relative to the cylindrical portion 321 by a guide mechanism composed of the guide grooves 321a and the guide pieces 722. One of the guide pieces 722 is formed in a recessed portion 723 that is formed on the enclosing member 72 so as to be recessed toward the inner side. This suppresses the increase in size of the entire switch device 1 caused by forming the guide mechanism. In this regard, the guide mechanism is not limited thereto. For example, guide grooves may be formed on the enclosing member 72 and guide pieces may be formed on the cylindrical portion 321.

As shown in FIGS. 2 to 4, the enclosing member 72 has the push portion 724 protruding rearward. The push portion 724 is in contact with the push button 61 of the mechanical switch 6 and pushes in the push button 61 when a pressing operation is performed on the operation area 21. Meanwhile, when the switch device 1 is not being operated by the user, the push portion 724 is elastically pressed toward the panel 2 by an elastic restoring force of the mechanical switch 6, and the translationally moving unit 7 is thereby pressed toward the panel 2.

Here, when viewed from the front side, the mechanical switch 6 presses the push portion 724 at an eccentric position relative to the translationally moving unit 7 as shown in FIG. 4, hence, there is a concern that tilt of the translationally moving unit 7 may occur. For this reason, in the first embodiment, two of three pairs of the guide groove 321a and the guide piece 722 engaging with each other (i.e., two pairs on the right and upper sides in FIG. 4) are formed to have a positional relationship in which the mechanical switch 6 is sandwiched therebetween when viewed from the front side. As a result, translational movement is guided in the vicinity of the mechanical switch 6, and instability of the orientation of the translationally moving unit 7 is suppressed.

In this regard, the enclosing member 72 can be omitted when, e.g., there is little concern that the lubricant on the sliding portion will reach the light guide 71. In this case, e.g., a guide mechanism to guide translational movement may be provided on the light guide 71.

The sensor sheet 8 is of the capacitance type and constitutes a self-capacitance touch sensor. In the first embodiment, the sensor sheet 8 detects proximity of a user’s finger to the operation areas 21 of the panel 2. The sensor sheet 8 is flexible.

Although the sensor sheet 8 is formed to bend in its thickness direction, FIG. 6 shows the sensor sheet 8 in a flattened, unfolded state. In FIG. 6, the bending position is indicated by a dash-dot line.

As shown in FIG. 6, the sensor sheet 8 includes a base material 81, and the detection conductive portion 82 provided on the base material 81. FIGS. 2 to 4 and 7 show the overall shape of the sensor sheet 8 without distinguishing between the base material and the detection conductive portion. The base material 81 is composed of a PET (polyethylene terephthalate) sheet, etc. which has electrical insulating properties, flexibility, and light-transmitting properties. As shown in FIG. 6, the base material 81 has a base portion 811 that is long in the left-right direction Y, four protruding pieces 812 that protrude from the base portion 811 on the same side, and a lead-out portion 813 that protrudes from the base portion 811 on the opposite side to the four protruding pieces 812. The four protruding pieces 812 are arranged at intervals in the left-right direction Y. Slits 814 are formed between adjacent protruding pieces 812. The slits 814 penetrate the base material 81 in the thickness direction, and are open on the side where the protruding pieces 812 protrude from the base portion 811 (on the upper side in FIG. 6).

The detection conductive portion 82 has light-transmitting properties and is formed on a surface of the base material 81. An example in which the detection conductive portion 82 is formed on the surface of the base material 81 on the light guide 71 side is shown in the first embodiment, but the detection conductive portion 82 may be provided on the surface of the base material 81 on the opposite side to the light guide 71. The detection conductive portion 82 is formed by, e.g., vapor deposition or printing, etc. For example, the detection conductive portion 82 is composed of an ITO film or transparent ink, etc. In areas where light does not need to pass through, the detection conductive portion 82 may be formed of a material that does not have light-transmitting properties. The detection conductive portion 82 includes four electrode portions 821 respectively formed on the four protruding pieces 812, and a wiring portion 823 that is electrically connected to the electrode portions 821 and is formed on the protruding pieces 812, the base portion 811, and the lead-out portion 813.

The electrode portion 821 is a portion capacitively coupled to a finger proximity to the operation area 21 and is designed to have a large surface area that faces the finger. The four electrode portions 821 are arranged side by side at intervals in the left-right direction Y.

The wiring portion 823 is thinner than the electrode portions 821, is formed in a linear shape, and is electrically connected to the electrode portions 821. In the first embodiment, the wiring portion 823 electrically connects the four electrode portions 821 to each other. That is, in the first embodiment, the sensor sheet 8 detects proximity of the user’s finger to any one of the four electrode portions 821, but does not identify proximity to which electrode portion 821.

The sensor sheet 8 is attached in a state of being bent in the thickness direction, and has four electrode sheet portions 84 and a wiring sheet portion 85 with a bent portion 83 therebetween. The bent portion 83 is formed at a position between the four electrode portions 821 and the base portion 811.

The electrode sheet portion 84 is a portion with the electrode portion 821 formed thereon, and is composed of a portion of the protruding piece 812 on the opposite side to the base portion 811. As shown in FIGS. 2 and 3, the electrode sheet portion 84 is sandwiched and held between the light guide 71 and the elastic panel 25, and adheres tightly to the front surface 71a of the light guide 71 and to a rear surface 251 of the elastic panel 25. The electrode sheet portion 84 is flexible and thus easily adheres tightly to the front surface 71a of the light guide 71. In addition, the electrode sheet portion 84 may be temporarily attached to the front surface 71a of the light guide 71 with a double-sided tape, etc. at, e.g., a position not blocking the light path from the light source 5 to the operation area 21. The light emitted from the light source 5 passes through the light guide 71, the electrode portion 821 and the base material 81 and reaches the panel 2.

The slits 814 are formed between the electrode sheet portions 84 adjacent to each other. Therefore, when one operation area 21 is pressed and the electrode sheet portion 84 corresponding to that operation area 21 moves rearward, the other electrode sheet portions 84 are prevented from being pulled by this movement.

The wiring sheet portion 85 is formed along the front-rear direction X and the left-right direction Y. The wiring sheet portion 85 is a portion with the wiring portion 823 formed thereon and is composed of portions of the protruding pieces 812 other than the electrode sheet portions 84, the base portion 811, and the lead-out portion 813.

Although not shown, the switch device 1 further includes a control unit. The control unit includes, e.g., a control area including a processor and a RAM (Random Access Memory) serving as an arithmetic area when the processor is operating, and a storage area having a ROM (Read Only Memory), a hard disk, etc., and storing programs executed by the processor, etc. The method of implementing the control unit is not limited to that using software as long as the control unit is configured to be able to execute its functions. For example, at least some of the functions of the control unit may be executed using hardware such as logic circuit.

The control unit receives detection results from the sensor sheet 8 and the four mechanical switches 6. When proximity of a finger to any of the operation areas 21 is detected using the sensor sheet 8, all the four light sources 5 are turned on so that the four marks 22a to 22d are visible. Then, when a pressing operation on an operation area 21 is detected by the mechanical switch 6, an instruction signal is transmitted to the air conditioner so that the corresponding function is executed. Then, once the proximity of the finger to the operation area 21 ends, the control unit turns off the light sources 5.

### Functions and Effects of the first embodiment

The switch device 1 in the first embodiment includes a pressing mechanism that generates a pressing force interacting between the panel 2, the sensor sheet 8, and the light guide 71. Therefore, the presence of an air layer between the panel 2, the sensor sheet 8 and the light guide 71 is suppressed, thereby suppressing reflection of light emitted from the light source 5 at the interface with the air layer. This suppresses loss of light from the light source 5 to the operation area 21.

In addition, the panel 2 has the elastic panel 25 that has elasticity and is in contact with the sensor sheet 8. Therefore, the elastic panel 25 easily elastically comes into tight contact with the sensor sheet 8, thereby further suppressing the presence of an air layer between the elastic panel 25 and the sensor sheet 8.

In addition, the pressing mechanism that generates a pressing force interacting between the panel 2, the sensor sheet 8, and the light guide 71 has an elastic unit that elastically presses the light guide 71 toward the panel 2. Since a space for arranging the light source 5, etc., is present on a side of the light guide 71 opposite to the panel 2, this arrangement space can be effectively used to arrange the elastic unit and this allows the entire switch device 1 to be small in size.

In addition, the mechanical switch 6 also serves as an elastic unit. Further reduction in the size of the switch device 1 is thereby realized.

In addition, the switch device 1 in the first embodiment includes the enclosing member 72 which surrounds around the light guide 71 and is fixed to the light guide 71, and the guide mechanism which is provided on the housing 3 and the enclosing member 72 and guides translational movement of the enclosing member 72 and the light guide 71 relative to the housing 3. Therefore, instability of the orientation of the enclosing member 72 and the light guide 71 is suppressed when the enclosing member 72 and the light guide 71 translationally move, and adhesion of lubricant or foreign matter, etc. present on the sliding portion to the light guide 71 is also suppressed.

In addition, the light guide 71 and the enclosing member 72 are fixed to each other by the fixing protrusions 713, 721 formed on at least one of the light guide 71 and the enclosing member 72. Therefore, a space is formed between the outer peripheral surface 71c of the light guide 71 and the enclosing member 72, which facilitates light reflection at the outer peripheral surface 71c of the light guide 71. Therefore, light leakage from the outer peripheral surface 71c of the light guide 71 is suppressed.

As described above, according to the first embodiment, it is possible to provide a switch device capable of suppressing loss of light from a light source to an operation area.

### Second embodiment

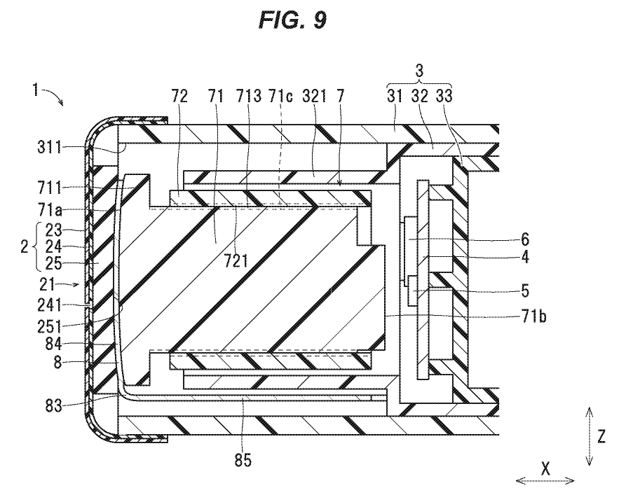

The second embodiment of the invention will be described with reference to FIGS. 8 and 9. FIG. 8 is a cross-sectional view showing the switch device 1, taken orthogonal to an up-down direction. FIG. 9 is a cross-sectional view showing the switch device 1, taken orthogonal to a left-right direction. The cross-sectional position of the switch device 1 in FIG. 8 is the same as that in FIG. 2, and the cross-sectional position of the switch device 1 in FIG. 9 is the same as that in FIG. 3.

In the second embodiment, the front surface 71a of the light guide 71, which is the surface in contact with the sensor sheet 8, is changed from that in the first embodiment. In particular, the front surface 71a in the second embodiment is formed in a curved shape that bulges toward the sensor sheet 8. In the second embodiment, the front surface 71a is formed in a spherical shape. For example, the front surface 71a is formed to have a curved shape that bulges toward the front both in a cross section orthogonal to the up-down direction Z as shown in FIG. 8 and in a cross section orthogonal to the left-right direction Y as shown in FIG. 9. Alternatively, the front surface 71a may be formed in an arched shape instead of a spherical shape.

Then, the electrode sheet portion 84 of the sensor sheet 8 is curved along the front surface 71a due to its flexibility. Similarly, the rear surface 251 of the elastic panel 25 is curved along the front surface 71a due to its elasticity.

The other configurations in the second embodiment are the same as in the first embodiment. Among the reference signs used in the second embodiment onwards, the same reference signs as those used in the already-described embodiment indicate the same constituent elements, etc., as those in the already-described embodiment, unless otherwise specified.

### Functions and Effects of the second embodiment

In the second embodiment, the front surface 71a of the light guide 71, which is the surface in contact with the sensor sheet 8, is formed in a curved shape that bulges toward the sensor sheet 8. As a result, when assembling the light guide 71, the sensor sheet 8 and the panel 2, the air between the light guide 71 and the sensor sheet 8 is likely to be pushed out and the air between the sensor sheet 8 and the panel 2 is also likely to be pushed out. Therefore, the light guide 71, the sensor sheet 8 and the panel 2 are reliably in tight contact with each other, thereby suppressing light loss caused by the presence of an air layer therebetween.

In addition, the same functions and effects as the first embodiment are also exerted.

### Modifications

Next, possible modifications of the switch device 1 in the first and second embodiments will be described.

The mechanical switch 6 in the first and second embodiments is the elastic unit that presses the light guide 71 and the enclosing member 72 toward the panel 2, but the elastic unit is not limited thereto and may be composed of an elastic member such as a coil spring, a plate spring, a disc spring, or rubber.

In addition, in the first and second embodiments, the pressing mechanism that generates a pressing force interacting between the panel 2, the sensor sheet 8, and the light guide 71 is realized by an elastic unit (in particular, the mechanical switch 6) that presses the light guide 71 toward the panel 2, but it is not limited thereto. For example, the mechanical switch 6 may be changed to a rigid member incapable of elastic deformation so that the elastic panel 25 is pressed toward the sensor sheet 8 and a pressing force between the panel 2, the sensor sheet 8 and the light guide 71 is generated by elasticity (i.e., restoring force) of the elastic panel 25.

In addition, the example in which the fixing protrusions 713 are provided on the light guide 71 and the fixing protrusions 721 on the enclosing member 72 has been described in the first and second embodiments, but it is not limited thereto, and the configuration may be such that fixing protrusions are provided on only one of the light guide 71 and the enclosing member 72.

In addition, the switch device 1 in the first and second embodiments is configured such that proximity of a finger to the operation area 21 is detected using the sensor sheet 8 and a pressing operation on the operation area 21 is detected using the mechanical switch 6, but the configuration is not limited thereto. For example, the mechanical switch 6 may be omitted by configuring to turn on the light sources 5 upon detection of proximity of a finger to the operation area 21 by the sensor sheet 8 and transmit a predetermined instruction to the air conditioner, etc., upon detection of contact with the operation area 21 (i.e., a touch operation) by the sensor sheet 8. In this case, the circuit of the sensor sheet 4 is configured so as to be able to detect which of the four operation areas 21 is touched. In addition, in this case, the light guide 71 does not need to move relative to the housing 3, allowing, e.g., the enclosing member 72 to be omitted.

Although the embodiments of the invention have been described, the invention according to claims is not to be limited to the above-described embodiments. Further, please note that not all combinations of the features described in the embodiments are necessary to solve the problem of the invention. In addition, the invention can be appropriately modified and implemented without departing from the gist thereof.

### REFERENCE SIGNS LIST

1 SWITCH DEVICE
2 PANEL
21 OPERATION AREA
25 ELASTIC PANEL
3 HOUSING
5 LIGHT SOURCE
6 MECHANICAL SWITCH
8 SENSOR SHEET
71 LIGHT GUIDE
713 FIXING PROTRUSION
72 ENCLOSING MEMBER
721 FIXING PROTRUSION

What is claimed is:

1. A switch device, comprising:
a panel comprising an operation area where an operation is performed by a user;
a light source that emits light onto the operation area;
a light guide that guides light emitted from the light source to the operation area;
a sensor sheet that detects proximity or contact of a finger of the user to or with the operation area, is sandwiched and held between the light guide and the panel, and transmits light output from the light guide; and
a pressing mechanism that generates a pressing force interacting between the panel, the sensor sheet, and the light guide.

2. The switch device according to claim 1, wherein the panel comprises an elastic panel that has elasticity and is in contact with the sensor sheet.

3. The switch device according to claim 2, wherein a surface of the light guide in contact with the sensor sheet is formed in a curved shape that bulges toward the sensor sheet.

4. The switch device according to claim 1, wherein the pressing mechanism comprises an elastic unit that elastically presses the light guide toward the panel.

5. The switch device according to claim 4, further comprising:
a mechanical switch that is pressed by a force during a pressing operation on the operation area that is applied through the sensor sheet and the light guide,
wherein the mechanical switch also serves as the elastic unit.

6. The switch device according to claim 1, further comprising:
a housing to which the panel is attached;
an enclosing member that surrounds around the light guide and is fixed to the light guide; and
a guide mechanism that is provided on the housing and the enclosing member and guides translational movement of the enclosing member and the light guide relative to the housing.

7. The switch device according to claim 6, wherein the light guide and the enclosing member are fixed to each other by a fixing protrusion formed on at least one of the light guide and the
enclosing member.

8. The switch device according to claim 1, wherein the pressing mechanism generates the pressing force so as to prevent an intervention of air layer between the panel, the sensor sheet, and the light guide.

9. The switch device according to claim 6, wherein the light guide and the enclosing member are fixed to each other by the fixing protrusion formed on at least one of the light guide and the enclosing member such that a space is formed between an outer peripheral surface of the light guide and the enclosing member.
